(19) United States
(12) Patent Application Publication
(10) Pub. No.: US 2006/0196423 A1
(43) Pub. Date: Sep. 7, 2006

(54) Gradually changed film coating device and tool for using in the coating device

(75) Inventor: Chien-Ming Huang, Taichung (TW)

Correspondence Address: TROXELL LAW OFFICE PLLC;SUITE 1404, 5205 LEESBURG PIKE, FALLS CHURCH, VA, 22041, US

(73) Assignee: Asia Optical Co., Inc.

(21) Appl. No.: 11/230,500

(22) Filed: Sep. 21, 2005

(30) Foreign Application Priority Data
Mar. 2, 2005 (TW) 094106336

(51) Int. Cl. C23C 16/00; C23C 14/00

(52) U.S. Cl. 118/720; 204/298.11

(57) ABSTRACT

A coating device includes a coating material source, and at least one substrate disposed opposite to the coating material source. The substrate has a coating surface that receives coating material from the coating material source to form a film thereon. A board is disposed on the coating surface of the substrate. The height and thickness of the board and the angle between the board and the substrate determines gradually changed slope and gradually changed area of the film on the board, whereby the slope and the area can be precisely controlled during the deposition process.

### BACKGROUND OF THE INVENTION

1. Field of the Invention

The present invention relates to a coating device and a tool used in the coating device, and more particularly to a coating device and a tool for coating an optical film thereon with a precise gradually changed slope and gradually changed area.

2. Description of the Related Art

In film-coating filed, coating a film with more than two kinds of thickness on a substrate, in particular, with a specific gradually changed slope, is difficult.

Conventional methods for coating a film with more than two different thickness in different sections on the same substrate are implemented by regulating the oblique angle of the substrate or using an assistant board during the coating process. Consequently, the thickness of the coating material on the substrate is different on different areas of the substrate. Thus, an optical film with various gradually changed effects is formed by changing the thickness of the film to thereby change the spectrum characteristic of the film. However, the thickness of the coating material cannot be precisely controlled by the above-mentioned methods.

FIG. 1 is a schematic view of a conventional coating device 5. The coating device 5 comprises a base 52 and a substrate 51 obliquely set above and spaced from the base 52. A target 53 is placed on the base 52 for forming a coating film 54 on the substrate 51 by sputtering or vapor-depositing. The substrate 51 is arranged at an oblique angle with respect to the base 52. The thickness of the coating film 54 is in an inverse proportion to the 1.5^{th} to 1.9^{th} order of the distance between the base 52 and the substrate 51. Therefore, the closer a portion of the substrate 51 is to the base 52, the larger the thickness at the portion of the coating film 54 is.

Although the oblique angle between the substrate 51 and the base 52 creates the coating film 54 having a gradually changed thickness on the substrate 51, a gradually changed slope at a specific point on the substrate 51 cannot be defined. When the substrate 51 is tilted at an angle with respected to the base 52, the gradient slope is pre-determined and the coating film 54 with the desired specific gradually changed slope is prohibited.

FIG. 2 shows another typical coating device 9 using an assistant board with different shape. The coating device 9 comprises a vacuum chamber 90, a coating umbrella 91 fixed on an upper portion of the vacuum chamber 90, an assistant board 92, and a coating material source 93. The coating umbrella 91 is pivotally fixed with an axis of a motor 94 and is drove by the motor 94 to rotate about the axis. The coating material source 93 is located opposite to the coating umbrella 91. The assistant board 92 is located adjacent to the coating umbrella 91 and between the coating material source 93 and the coating umbrella 91. The coating umbrella 91 has a plurality of coating holes (not shown) in which a plurality of substrates 95 is fixed and a fix hole 910 receiving the axis of the motor 94. The shape of the assistant board 92 and its position on the coating umbrella 91 will determine the thickness of the film on the substrate 95. The detailed structure of the coating device 9 can be referred to Taiwan Patent Publication No. 540585.

During the coating process using the coating device 9, the plurality of substrates 95 are fixed on the coating umbrella 91. The motor 94 then drives the coating umbrella 91 to rotate and the coating material source 93 sputters or vapor-deposits coating material on the substrate 95. After the substrates 95 each are coated with one or more layers of coating material, the substrates 95 are detached from the coating umbrella 91 and other substrates 95 are put in the vacuum chamber 90. Because there is a long distance between the assistant board 92 and the substrate 95, it is difficult to precisely control the thickness of the coating on the substrate 95.

Taiwan Patent Publication No. M249958 disclosed another coating device. The coating device includes at least two coating material sources and at least two corresponding assistant boards. Similar to the device discussed above with reference to FIG. 2, it is also difficult for this coating device to precisely control the film with the gradually changed slope and the gradually changed area.

### SUMMARY OF THE INVENTION

Thus, an object of the present invention is to provide a coating device and a tool used in the coating device, the coating device can form a film which gradually changed slope and gradually changed area are precisely controlled.

In order to achieve the above-mentioned object, the coating device in accordance with the present invention comprises a coating material source that supplies a coating material, and a substrate opposite to the coating material source. The substrate has a coating surface, which receives the coating material to form a film thereon. A board having predetermined height and thickness is arranged between the coating surface of the substrate and the coating material source. The board is rotatable with respect to the coating surface to selectively set an included angle between the board and the coating surface. By changing the height and thickness of the board and the included angle, the film is formed with a gradually changed slope and a gradually changed area.

The substrate is arranged to be rotatable about an axis. A coating umbrella is rotatable about the axis and defines a hole for receiving and fixing the substrate therein. The substrate is surrounded by a frame having opposite sides between which the board is rotatably mounted. The coating device further comprises a vacuum chamber in an upper portion of which the coating umbrella is arranged, and the coating umbrella is coupled to and driven by a motor to rotate about the axis.

The present invention also provides a tool used in the coating device. The tool comprises a frame adapted to receive and removably retain a substrate therein with a coating surface of the substrate receiving a coating material from a coating material source to form a film thereon; and a board having a height and thickness adjustably mounted on the frame and between the coating surface of the substrate and the coating material source, whereby by changing the height and thickness of the board and an included angle between the board and the coating surface, the film is formed with a gradually changed slope and a gradually changed area.

The gradually changed slope and area of the film are precisely controlled by the coating device according to the invention.

### BRIEF DESCRIPTION OF THE DRAWINGS

FIG. 1 is a schematic view showing a conventional coating device;

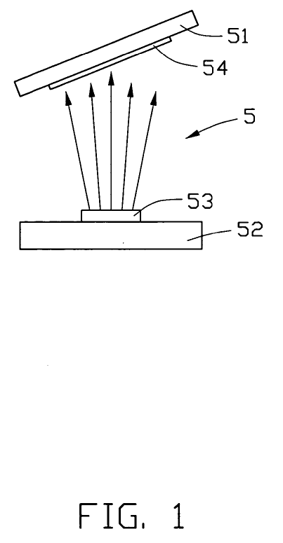

FIG. 2 is a schematic view showing another conventional coating device;

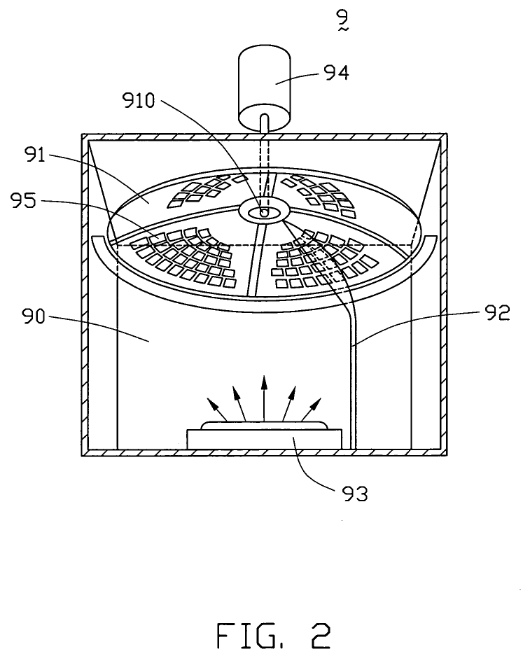

FIG. 3 is a schematic view of a coating device according to a preferred embodiment of the invention;

FIG. 4 is a schematic view of a tool used in the coating device shown in FIG. 3; and

FIG. 5 is a schematic view of a tool according to a second preferred embodiment of the invention.

### DETAILED DESCRIPTION OF THE INVENTION

It will be understood that the illustration is for the purpose of describing preferred embodiments of the invention and is not intended to limit the invention thereto.

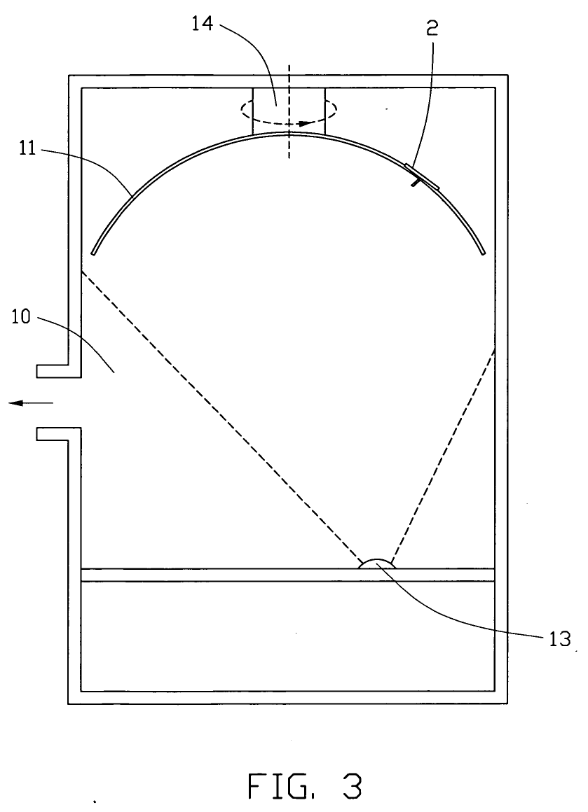

Referring to FIG. 3, a coating device constructed in accordance with the present invention comprises a vacuum chamber 10, which can be evacuated by a vacuum pump, a coating umbrella 11 fixed in an upper portion of the vacuum chamber 10, a plurality of tools 2 (only one shown in the drawings) installed on the coating umbrella 11, and a coating material source 13 arranged in a lower portion of the vacuum chamber 10.

The coating umbrella 11 is coupled to and driven by a motor 14 to rotate about an axis that is shown in dashed line in FIG. 3. The coating material source 93 is located opposite to the coating umbrella 11 and preferably offsets from a vertical center line of the coating umbrella 11, which can be coincident with the rotation axis of the umbrella 11. The coating umbrella 11 forms a plurality of coating holes (not shown) for fixing the tools 2 therein, respectively.

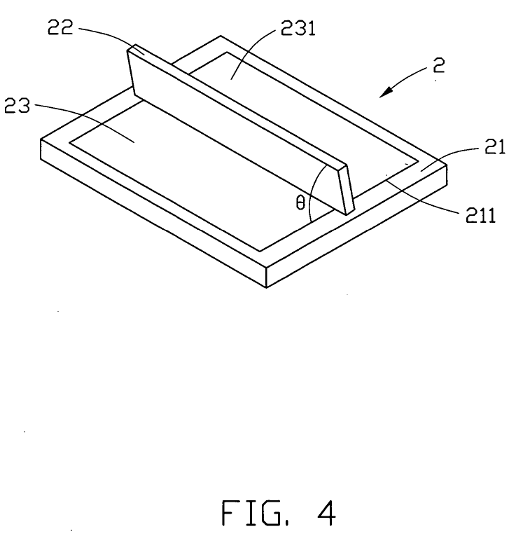

Referring to FIG. 4, the tool 2 is constructed to receive and retain a rectangular substrate 23 therein. The substrate 23 has a surface 231, which will be referred to as “coating surface” hereinafter, to receive a coating material from the coating material source 13 to form a film thereon. The tool 2 comprises a frame 21 surrounding the substrate 23. In the embodiment illustrated, the frame 12 is rectangular, corresponding to the rectangular shape of the substrate 23. A board 22 is mounted to the frame 21, and preferably straddling between opposite sides of the frame 21 and opposing the coating surface 231 of the substrate 23. The board 22 is allowed to rotate with respect to the frame 21. The board 22 has predetermined height and thickness and is inclined with respect to the frame.21 and the substrate 23 at a predetermined oblique angle that is denoted by symbol “θ” in FIG. 4.

The tool 2 is mounted on the coating umbrella 11 in such a way that the substrate 23 is located on an outer surface of the coating umbrella 11 and that the board 22 partially extends through the coating hole of the coating umbrella 11 and into an interior of the coating umbrella 11. Thus, the coating surface 231 of the substrate 23 faces the coating material source 13 through the coating hole. The coating material emitted from the coating material source 13 travels through the coating hole of the coating umbrella 11 and reaches and deposits on the coating surface 231 of the substrate 23 to form the coating film.

During the coating process, the motor 14 rotates the coating umbrella 11, while the coating material source 13 emits the coating material that is sputtered onto or vapor-deposited onto the coating surface 231 of the substrate 23 in a vacuum. After the coating surface 231 is coated with one or more layers of coating material, which form the coating film, the tool 2 is detached from the coating umbrella and removed out of the vacuum chamber 10. Other sets of tools retaining new substrates 23 are put in the vacuum chamber 10 for the next cycle of coating operation.

Because the distance between the board 22 and the substrate 23 is short, the thickness of the film on the substrate 23 can be precisely controlled by the board 22. The height and thickness of the board 22 and the included angle between the board 22 and the substrate 23 are selected to precisely control the amount of the coating material adhered to the substrate 23 and thus the thickness at different areas of the film formed on the substrate 23. This will be further described. Thus, the optical film with different gradually change effects can be formed by changing the thickness of the film to thereby change the spectrum characteristic of the film. Due to the board 22 of the tool 2, the coating material emitted from different positions of the coating material source 23 forms different amount of the coating on the coating surface 231, thus the thickness of the coating film on the substrate 23 gradually changes. Furthermore, the substrate 23 has a movement relative to the coating material source 13 when the coating umbrella 11 rotates, so the gradually changed area of the film is increased, and the gradually changed slope is altered. Therefore, to precisely control the gradually changed slope and the gradually changed area, the tool must be designed according to specific parameters, such as the gradually changed slope and gradually changed area of the film.

The height and thickness of the board 22 and angle between the board 22 and the substrate 23 influence the gradually changed slope and gradually changed area of the coating film on the substrate 23 and are described as follows:

1. Height of the Board 22 (H)

The greater the height of the board 22 is, the larger the gradually changed area is. The smaller the height of the board 22 is, the less the gradually changed area is. The height of the board 22 also influences the gradually changed slope.
H=K·D
where “K” is a constant determined by the material of the coating material source, curvature of the coating umbrella 11, and parameters of the vaporization and “D” represents the gradually changed area.
2. Angle Between the Board 22 and the Substrate 23 (θ)

The angle between the board 22 and the substrate 23 is an angle from 0° to 180°. It is preferred that the angle is selected from the range between 45° to 135°. For the board 22 of a given height, the larger the absolute value of the difference |90−θ| is, the larger the gradually changed area is. For instance, assuming the height of the board 22 is 22 mm, when θ=90°, the gradually changed area is 6.3 mm, and when θ=70°, the gradually changed area is 8.5 mm.

3. The thickness of the board 22 influences the area without film. The larger the thickness of the board 22 is, the larger the area without film is.

4. The substrate 23 located on different circles of the coating umbrella 11 has different angles with respect to the coating material source 13. Thus, the height of the board 22 and the angle between the board 22 and the substrate 23 should be properly designed to achieve the substrates having the same gradually changed area and gradually changed slope.

Thus, considering all of the above-mentioned factors, a gradually changed film with predetermined gradually changed slope and area can be designed. The gradually changed slope and area are precisely controlled.

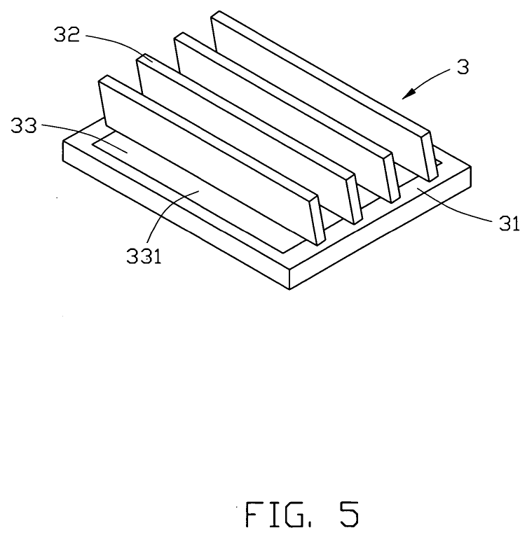

Referring to FIG. 5, a tool 3 according to a second preferred embodiment comprises a rectangular substrate 33. The substrate 33 has a coating surface 331 adapted to receive coating material from the coating material source to form a film thereon. A frame 31 surrounds the substrate 33 along four sides thereof. A number of parallel boards 32 are mounted to the frame 31, straddling between opposite sides of the frame 31. The boards 32 are rotatable relative to the frame 31. The board 32 locates on the coating surface 331 of the substrate 33. The board 32 has predetermined height, thickness, and angle with respect to the substrate 23.

Thus, similar to the illustration with reference to the first embodiment, by changing the angular position of each board 32 with respect to the substrate, the film formed of the coating material on the coating surface 331 can be regulated. Further, by setting the height and thickness of each board 32, the film can also be regulated.

What is claimed is:

1. A gradually changed film coating device, comprising:
a coating material source that supplies a coating material;
a substrate opposite to the coating material source, the substrate having a coating surface, which receives the coating material from the material source to form a film thereon; and
a board having predetermined height and thickness, arranged between the coating surface of the substrate and the coating material source, the board being rotatable with respect to the coating surface to selectively set an included angle between the board and the coating surface, whereby by changing the height and thickness of the board and the included angle, the film is formed with a gradually changed slope and a gradually changed area.

2. The gradually changed film coating device as claimed in claim 1, wherein the substrate is rotatable about an axis.

3. The gradually changed film coating device as claimed in claim 2 further comprising a coating umbrella rotatable about the axis, the coating umbrella defining a hole for receiving and fixing the substrate therein.

4. The gradually changed film coating device as claimed in claim 3 further comprising a vacuum chamber in an upper portion of which the coating umbrella is arranged, the coating umbrella being coupled to and driven by a motor to rotate about the axis.

5. The gradually changed film coating device as claimed in claim 4, wherein the coating material source is arranged at a lower portion of the vacuum chamber and offsets from the axis.

6. The gradually changed film coating device as claimed in claim 1, wherein the substrate is surrounded by a frame having opposite sides between which the board is rotatably mounted.

7. The gradually changed film coating device as claimed in claim 1, wherein the included angle between the board and the substrate is between 0 to 180 degrees.

8. The gradually changed film coating device as claimed in claim 1, wherein the included angle between the board and the substrate is between 45 to 135 degrees.

9. A tool for using in a film coating device, comprising:
a frame adapted to receive and removably retain a substrate therein with a coating surface of the substrate receiving a coating material from a coating material source to form a film thereon; and
a board having a height and thickness adjustably mounted on the frame and between the coating surface of the substrate and the coating material source, whereby by changing the height and thickness of the board and an included angle between the board and the coating surface, the film is formed with a gradually changed slope and a gradually changed area.

10. The tool as claimed in claim 9, wherein the frame surrounding the substrate has opposite sides between which the board is rotatably mounted.

11. The tool as claimed in claim 9, wherein the relationship between the height of the board and the gradually changed area is:
H=K·D
where H represents the height of the board; K is a constant determined by the material of the coating material source and curvature of the coating umbrella; and D represents the gradually changed area.

12. The tool as claimed in claim 9, wherein the included angle between the board and the substrate is between 0 to 180 degrees.

13. The tool as claimed in claim 9, wherein the included angle between the board and the substrate is between 45 to 135 degrees.

14. The tool as claimed in claim 9, wherein a number of parallel boards are mounted to the frame, straddling between opposite sides of the frame, and each board has a special height, thickness, and angle between the board and the substrate.

15. The tool as claimed in claim 9, wherein the coating device is either a sputtering coating device or a vapor-deposited coating device.

16. The tool as claimed in claim 15, wherein the coating device further comprises a vacuum chamber and a coating umbrella arranges on an upper portion of the vacuum chamber.

17. The tool as claimed in claim 16, wherein the coating umbrella is coupled to an axis of a motor and drove by a motor to rotate about the axis.

18. The tool as claimed in claim 17, wherein the coating material source is arranged at a lower portion of the vacuum chamber and offsets from the axis.

19. The tool as claimed in claim 18, wherein the coating umbrella defines a hole receiving and fixing the substrate therein.
